(19) United States
(12) Patent Application Publication
(10) Pub. No.: US 2026/0246437 A1
(43) Pub. Date: Aug. 20, 2026

(54) DOOR OPENER WITH SECURE REMOTE ACTUATOR PAIRING

(71) Applicant: ASSA ABLOY Entrance Systems AB, Landskrona (SE)

(72) Inventors: Vickie LENTS, Winston-Salem, NC (US); David P. BRESSON, Pfafftown, NC (US); Davide BRAGGION, Milan (IT); Juan Jorge LLORET MADRID, Noventa Padovana (IT)

(21) Appl. No.: 19/056,864

(22) Filed: Feb. 19, 2025

(51) Int. Cl. H03G 3/30; E05F 15/668; E05F 15/77

(52) U.S. Cl. CPC H03G 3/3036; E05F 15/668; E05F 15/77; E05Y 2900/106; H03G 2201/103

(57) ABSTRACT

A remotely operable movable barrier opener may include a motor operable to transition the movable barrier between open and closed positions, a receiver configured to receive a transmitted signal from a remote transmitter, and a controller including processing circuitry configured to determine whether the transmitted signal is from an authorized remote operator and activate the motor in response to the transmitted signal being determined to be from the authorized remote operator. The controller may be further configured to reduce a sensitivity of the receiver of the opener in response to the opener executing a pairing process and increase the sensitivity of the receiver of the opener in response to completing the pairing process.

### TECHNICAL FIELD

Example embodiments generally relate to movable barriers, such as sectional garage doors and, in particular, relate to an opener for such a movable barrier that has the ability to increase security when in a pairing mode to pair with a remote actuator.

### BACKGROUND

Moveable barriers including sectional doors, such as garage doors, are commonly used to partition or enclose spaces. Just as commonly, an automated opening device is connected to the sectional doors in order to easily and remotely open or close the doors. As an example, a large portion of sectional doors for both residential and industrial applications employ an installed garage door opener (GDO) to automatically open and close the sectional doors based on the actuation of a local or remote actuator (that is often simply referred to as a “remote”) that causes an operator or motor to operate to move the movable barrier when actuated.

In a typical situation, the user is physically present when the local actuator is used, and the actuation may occur responsive to a wired connection, or via a short range wireless connection, between the local actuator and the operator. When the remote actuator is used, the remote actuator is typically in a vehicle of the user, or sometimes carried on the person of the user, and uses wireless connections that are capable of communication at greater ranges (e.g., a few houses away down the street). In this regard, a receiver at the operator “listens” for transmissions from the remote actuator and, when a transmission is received from a recognized and authorized remote actuator, the operator triggers operation of the motor or operator to move the movable barrier.

Many GDO products allow the addition and removal of remote actuators so that the user can have the convenience of not needing to move a limited number of remote actuators to various different use contexts. For example, each vehicle, each family member, each worker, or each user in various other situations where a multiplicity of users are desired, may possess a remote actuator, and the remote actuator may be authorized and able to actuate the operator from a distance.

The authorization of a particular remote actuator for interaction and communication with the operator is typically accomplished via a well-known process that is typically referred to as “pairing.” The pairing process is often entered by pressing a button on the operator itself, or more recently also via interaction via a smart phone application (or “app”) responsive to authentication of the user. When pairing is initiated, a controller of the operator enters a mode in which the receiver of the operator is used to scan for transmissions from a remote actuator. Whereas outside the pairing mode, only previously paired devices may cause actuation of the operator, while in the pairing mode, new or previously unrecognized remote actuators can be recognized as being authorized to operate the GDO and move the movable barrier remotely. When the pairing mode is exited, only those previously paired remote actuators may be able to actuate the operator to move the movable barrier.

A problem that can be encountered in the context above is that another and unintended transmission may be received while the controller is in the pairing mode. Although the unintended transmitter could be that of a nefarious actor, the more common case is that it is a neighbor who just coincidentally happens to be within range and transmitting to his/her own GDO. Even this more likely scenario, every time the neighbor attempts to open his/her garage door, the user may experience a door open/close event that is undesirable, which can be very annoying. Accordingly, it would be desirable to provide a technical solution to the problem noted above.

### BRIEF SUMMARY OF SOME EXAMPLES

In an example embodiment, a method of pairing a remote actuator with an opener operably coupled to a movable barrier may be provided. The method may include receiving an indication that the opener is entering a pairing mode in which a transmitted code associated with the remote actuator is learnable by the opener, reducing a sensitivity of a receiver of the opener in response to the indication, operating the receiver of the opener at reduced sensitivity during a pairing process associated with the pairing mode, and increasing the sensitivity of the receiver of the opener in response to exiting the pairing mode.

In another example embodiment, a remotely operable movable barrier opener may be provided. The opener may include a motor operable to transition the movable barrier between an open position and a closed position, a receiver configured to receive a transmitted signal from a remote transmitter, and a controller including processing circuitry configured to determine whether the transmitted signal is from an authorized remote operator and activate the motor in response to the transmitted signal being determined to be from the authorized remote operator. The controller may be further configured to reduce a sensitivity of the receiver of the opener in response to the opener executing a pairing process and increase the sensitivity of the receiver of the opener in response to completing the pairing process.

In another example embodiment, a system for remotely operating a movable barrier may be provided. The system may include a movable barrier, an opener operably coupled to the movable barrier to transition the movable barrier between an open position and a closed position, and a remote transmitter. The opener may include a receiver configured to receive a transmitted signal from a remote transmitter, and a controller comprising processing circuitry configured to determine whether the transmitted signal is from an authorized remote operator and activate the motor in response to the transmitted signal being determined to be from the authorized remote operator. The controller is further configured to reduce a sensitivity of the receiver of the opener in response to the opener executing a pairing process and increase the sensitivity of the receiver of the opener in response to completing the pairing process.

### BRIEF DESCRIPTION OF THE SEVERAL VIEWS OF THE DRAWING(S)

Having thus described some example embodiments in general terms, reference will now be made to the accompanying drawings, which are not necessarily drawn to scale, and wherein:

FIG. 1 illustrates a perspective view of a door opener system in a ceiling mounted or trolley configuration in accordance with an example embodiment;

FIG. 2 illustrates a block diagram of such a system configured to increase security of remote actuator pairing in accordance with an example embodiment; and

FIG. 3 illustrates a method for increasing security or remote actuator pairing in accordance with an example embodiment.

### DETAILED DESCRIPTION

Some example embodiments now will be described more fully hereinafter with reference to the accompanying drawings, in which some, but not all example embodiments are shown. Indeed, the examples described and pictured herein should not be construed as being limiting as to the scope, applicability or configuration of the present disclosure. Rather, these example embodiments are provided so that this disclosure will satisfy applicable legal requirements. Like reference numerals refer to like elements throughout. Furthermore, as used herein, the term “or” is to be interpreted as a logical operator that results in true whenever one or more of its operands are true. As used herein, operable coupling should be understood to relate to direct or indirect connection that, in either case, enables functional interconnection of components that are operably coupled to each other.

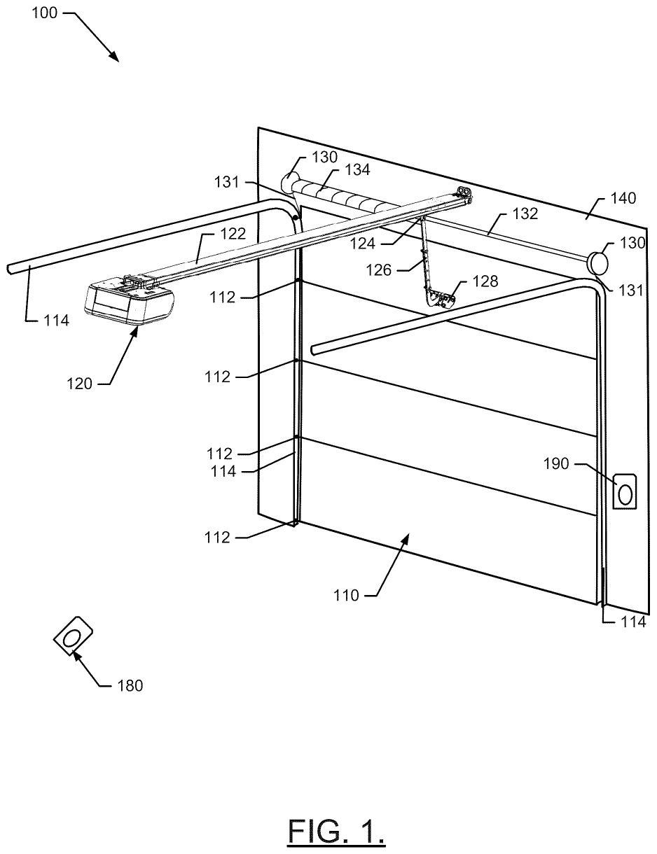

As indicated above, an undesired pairing can occur in relatively rare instances. Nevertheless, the rarity of the situation itself is not sufficient to warrant ignoring the issue, and a technical solution for improving systems involving movable barriers that are operated responsive to remote actuation is therefore desirable. Example embodiments address the problem by controlling the sensitivity of the receiver during the pairing mode so that only relatively close transmitters can be paired during the pairing process. FIG. 1 illustrate a system in which example embodiments may be employed.

More particularly, FIG. 1 illustrates a garage door operator (GDO) system 100 of an example embodiment. In this regard, FIG. 1 shows the GDO system 100 in a trolley (or ceiling mounted) configuration, but it should be understood that example embodiments may also apply to situations in which the GDO system 100 is in a jackshaft configuration. In both cases, the GDO system 100 includes a sectional door 110, in which each section of the door has rollers 112 operably coupled to opposing lateral sides of the sections. The rollers 112 are typically rotatably operably coupled to the sectional door 110 via brackets that rotatably support a shaft of the rollers 112 and enable a wheel to extend into and ride within rails 114 disposed on opposing sides of the sectional door 110 as the sectional door 110 transitions between open and closed positions. The sectional door 110 of FIG. 1 is shown in the closed position, where the rollers 112 are in a vertical section of the rails 114. Thus, it can be appreciated that in the open position the rollers 112 are located in a horizontally extending portion of the rails 114, and the sectional door 110 is carried into parallel with the ground as opposed to its condition of being perpendicular to the ground in the closed position shown in FIG. 1. Each section of the sectional door 110 can pivot relative to any adjacent section at an intersection thereof in order to enable the sectional door 110 to traverse the bend that separates the horizontally extending portion of the rails 114 from the vertically extending portion of the rails 114.

FIG. 1 also illustrates a GDO unit referred to as an opener 120 or motorhead. The opener 120 of this example is shown in the trolley configuration in which a guide rail 122 may extend parallel to and approximately midway between the horizontally extending portion of the rails 114 on opposing lateral sides of the sectional door 110. The opener 120 may be mounted (e.g., from the ceiling) proximate to an end of the guide rail 122 to drive a trolley 124 along the guide rail 122 via a flexible member such as a belt, cable or chain. In particular, the flexible member may be driven and moved responsive to operation of an operator such as an electric motor. The belt, cable or chain may also be operably coupled (e.g., via the trolley 124) to a top portion of the sectional door 110 by an engaging arm 126 and engaging bracket 128 that is attached to the sectional door 110. As noted above, the trolley 124 may be manually released from the sectional door 110 to allow for manual repositioning of the sectional door 110.

In some cases, the sectional door 110 may also be supported by one or more instances of cables 131 that are alternately wound onto and off of one or more cable drums 130 disposed at or near opposing ends of a tube 132 (sometimes called a drive tube). The cables 131 may be attached to a bottom portion of the sectional door 110 to assist in carrying the weight of the sectional door 110. The tube 132 may further support a spring assembly 134 that facilitates, along with the cables 131, supporting the weight of the sectional door 110 during opening and closing operations of the sectional door 110 using the opener 120. The sectional door 110, when closed, may block an opening provided in a front wall 140 of the garage in which the GDO system 100 is installed. The opening may be left open when the sectional door 110 is raised onto the horizontally extending portions of the rails 114. As can be seen in FIG. 1, the guide rail 122 may be secured to the front wall 140 at a proximal end of the guide rail 122, and the opener 120 may be suspended from the ceiling of the garage at a distal end of the guide rail 122.

The sectional door 110 is, as noted above, often comprised of panels of aluminum, steel, fiberglass, plastic, or other relatively lightweight, but otherwise structurally rigid material of any suitable type. In some cases, one or more of the panels of the sectional door 110 may include or be comprised of a glass or film that may be transparent or translucent to allow natural light to pass therethrough and into the garage or other space to which the sectional door 110 provides access. The opener 120 draws power, typically from an alternating current (AC) mains power supply, which may be accessed by corded connection to a power supply outlet.

The opener 120 may be actuated by one or more instances of an actuator, which may include a movable actuator (e.g., remote actuator 180) and a fixed actuator 190, which may be mounted on a wall or at the opener 120. Notably, although the fixed actuator 190 of FIG. 1 is located at the front wall, the fixed actuator 190 may alternatively be located at a back wall or any sidewall of the garage (or other location in which the operator system is employed). The remote actuator 180 may be located in a vehicle, or may be carried by the user, or otherwise be movable and usable when within range of the opener 120 to wirelessly instruct the opener 120 to operate to open or close the sectional door 110. The fixed actuator 190 and/or the remote actuator 180 may include a simple button or other actuator to operate the opener 120. However, in other examples, the fixed actuator 190 and/or remote actuator 180 may include a display (e.g., touch screen display) or other more complicated user interface to enable control of the opener 120 in addition to other functions associated with operation, monitoring or control of the GDO system 100.

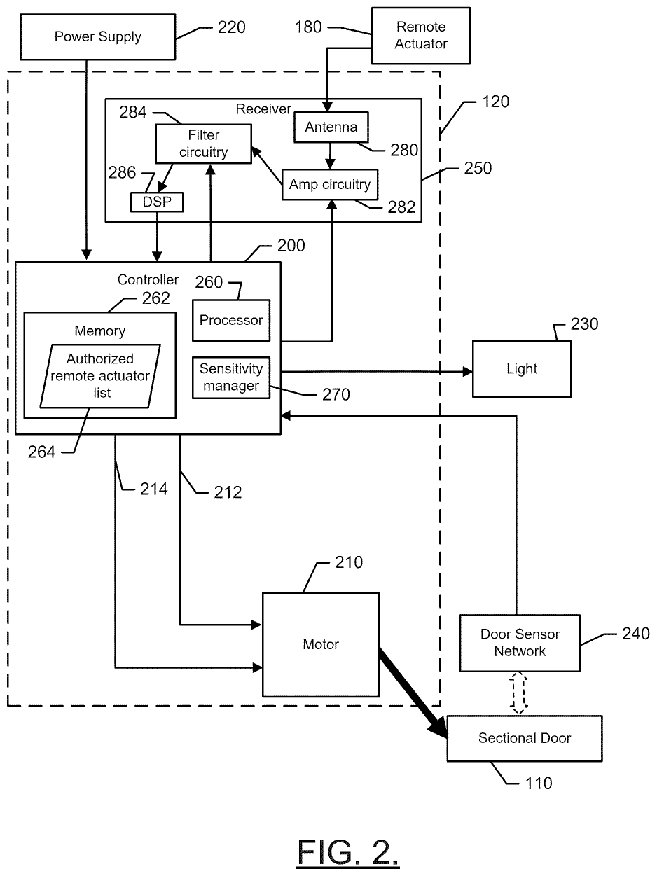

As noted above, the remote actuator 180 may be paired with the opener 120 via a pairing process, and may be one of potentially multiple remote actuators that may be paired with the opener 120 and therefore authorized to actuate the opener 120. The opener 120 of example embodiments may be modified as described herein to increase the security of that pairing process, and FIG. 2 is aimed at defining an example context in which such modification may be accomplished. Notably, the sectional door 110 is merely one example of a movable barrier upon which the opener 120 may operate. In other embodiments, gates, doors, partitions and barriers of other types may also be operated by respective other instances of the opener 120. In such cases, to the extent remote actuators are paired with the opener 120, the pairing will be accomplished as described herein.

Turning to FIG. 2, a block diagram of various components of a GDO system of an example embodiment is shown. In particular, various internal components of the opener 120 of FIG. 1 are shown. However, the GDO system and its movement of the sectional door 110 should be remembered to be simply one example system in which a movable barrier is moved responsive to actuation from the remote actuator 180 where the remote actuator 180 is an authorized actuator for the opener 120 via a pairing process. In an example embodiment, the opener 120 may include a controller 200 and a motor 210. The motor 210 may operate under control of the controller 200, which may receive power from a power supply 220 (e.g., mains power), and may regulate the provision of power to the motor 210 to control both the operation of the motor 210 and the direction of the operation (e.g., closing or opening). In some cases, the controller 200 may provide separate power to the windings of the motor 210 for forward (e.g., closing) and reverse (e.g., opening) directions of operation, and such power may be provided as a forward power connection 212 and a reverse power connection 214.

In an example embodiment, the controller 200 may also selectively provide power to a light 230. In some cases, the light 230 may be a general space illumination device that illuminates surrounding areas whenever the motor 210 operates (and for some period thereafter, or when otherwise turned on via the controller 200). However, the light 230 may also or alternatively be used to indicate a current mode or provide information regarding progress or completion of steps or operations of a process associated with the current mode. For example, the light 230 may flash according to a given pattern to indicate that the opener 120 is in the pairing mode, or the light 230 may flash to indicate that inputs are received or not received, or that steps are completed or not completed, in association with performance of the pairing process while in the pairing mode.

In an example embodiment, a door sensor network 240 may be disposed on or proximate to the sectional door 110 to monitor aspects of the movement of the sectional door 110 and/or its environment. The door sensor network 240 may include motion, speed, force and other sensors associated with movement of the sectional door 110 including, for example, limit switches that determine respective limits for motion of the sectional door 110 in both the opening and closing directions. Moreover, the door sensor network 240 may also include an obstruction sensor, which may detect when an object is between the sectional door 110 and the ground beneath the sectional door 110 to ensure that the sectional door 110 does not close on the object. In some cases, the obstruction sensor may include an infrared or other beam emitter, and a corresponding beam receiver that provides an input to the controller 200 to indicate that the beam emitted by the beam emitter is not being received at the beam receiver (e.g. due to the object, or misalignment of the emitter and receiver). When the controller 200 receives the input from the obstruction sensor, the controller 200 stops provision of power to the motor 210 to stop movement of the motor 210. Similarly, when the limit switches are triggered, the controller 200 is informed and stops movement of the motor 210, which in most cases simply means stopping the provision of power via both the forward and reverse power connections 212 and 214.

In an example embodiment, the controller 200 may be operable responsive to input from the remote actuator 180, as discussed above in general terms. However, more specifically, the remote actuator 180 may transmit a signal at a particular frequency that is generally within a band of frequencies to which a receiver 250 of the opener 120 is tuned. In some embodiments, the remote actuator 180 may further generate a code in or via its transmitted signal, and the code may uniquely identify the remote actuator 180. The controller 200 may include processing circuitry that is configured to control the operation of the opener 120. In this regard, for example, the processing circuitry may include a processor 260 and memory 262. The memory 262 may store data, applications (e.g., for execution by the processor 260) or any other suitable information for local or remote usage consistent with the descriptions provided herein. In some cases, the processing circuitry may be part of a printed circuit board (PCB), application specific integrated circuit (ASIC) or other integrated circuit (IC) chip, board or the like. The processing circuitry may therefore, depending on its configuration (e.g., via hardware, firmware and/or software) enable the controller 200 to execute coordinated control over the motor 210 responsive to actuation from authorized sources, which may include any remote actuators having a code that has been previously learned, and thereafter stored in the memory 262. In some cases, the learned or stored codes may form or be considered to form an authorized remote actuator list 264. Thus, for example, whenever the receiver 250 receives a transmission in the band of frequencies to which the receiver 250 is generally tuned and therefor sensitive, the code of the transmission received may be checked against the authorized remote actuator list 264. If the code of the transmission received matches one of the codes in the authorized remote actuator list 264, the controller 200 may actuate the motor 210 to open or close the sectional door 110. If the code of the transmission received does not match one of the codes in the authorized remote actuator list 264, no action may be taken and the motor 210 is not operated.

As can be appreciated from the discussion above, when the opener 120 is placed in the pairing mode (or learning mode), the controller 200 enables transmissions with new codes to be added to the authorized remote actuator list 264. In this regard, when the controller 200 places the opener 120 in the pairing mode (e.g., via selection of a button commanding transition to the pairing mode locally at the opener 120, or via instructions received via the app), if the code of the transmission received does not match one of the codes in the authorized remote actuator list 264, the code is added to the authorized remote actuator list 264. To prevent inadvertent addition of a code nefariously or coincidentally transmitted while the controller 200 has the opener 120 in the pairing mode, example embodiments may operate to reduce the sensitivity of the receiver 250. In this regard, it can generally be assumed that the user who is adding a remote actuator to the authorized remote actuator list 264 will be fairly close to the opener 120 when doing so. Whereas, when the same user is approaching the opener 120 in a vehicle and desires to operate the opener 120, the range is desirably much larger (and similar perhaps to the range of the inadvertent or undesired transmitter that might accidentally be added to the authorized remote actuator list 264). Accordingly, by reducing the sensitivity of the receiver 250 in the pairing mode, the opener 120 may effectively be prevented from receiving more distant transmissions, and may only be able to receive transmissions a short distance away from the opener 120 (and therefore also more likely to be limited only to the remote actuators that are specifically intended to be learned or paired).

Accordingly, the opener 120 of an example embodiment may be configured to reduce the sensitivity of the receiver 250 in the pairing mode (i.e., relative to its normal operating sensitivity when not in the pairing mode). The opener 120 may accomplish the adjustment of receiver sensitivity in various different ways. In some cases, the controller 200 may employ a sensitivity manager 270, which may be instantiated as an application stored in memory (e.g., memory 262) and executed by a processor (e.g., processor 260), or which may be instantiated in firmware, via a field programmable gate array (FPGA), dedicated integrated circuity, or other means. Regardless of how accomplished, the controller 200 (e.g., via the sensitivity manager 270) may reduce sensitivity of the receiver 250 when transitioning into the pairing mode, and may increase the sensitivity of the receiver 250 (e.g., restoring it to normal operating levels) when transitioning out of the pairing mode.

Although the receiver 250 may be structured in any of various ways, and therefore the adjustment of sensitivity may also be accomplished in different ways, some general components of a typical embodiment of the receiver 250 are shown in FIG. 2 to provide a basis for describing some examples. In this regard, the receiver 250 may include an antenna 280 that is configured to receive transmissions (e.g., transmitted signals) from the remote actuator 180. The signals received at the antenna 280 may be amplified and filtered (e.g., via amplification circuitry 282 and filter circuitry 284, respectively) prior to being digitized and processed by a digital signal processor (DSP). The amplification circuitry 282 may include one or more amplifiers that amplify signals received by the antenna 280. The filter circuitry 284 may include one or more filters that, for example, suppress signals that are not within a particular range of frequencies (e.g., a range of frequencies defining desired signals or signal frequencies). The controller 200 may, in some cases, interact with one or more of these components of the receiver 250 to modify the sensitivity of the receiver 250 to prevent undesired learning of remote actuators in the pairing (or learning) mode.

Receiver sensitivity adjustment is, in some cases, generally controlled by adjusting receiver gain. In general terms, the sensitivity of the receiver 250 is a function of the ability of the receiver 250 to discriminate a desired signal from the noise in its environment. Adjusting the gain of the receiver 250 refers to the process of changing the amplification level of the signal received by the receiver 250. The adjustment of the amplification level essentially controls how sensitive the receiver 250 is to incoming signals by adjusting the strength of the signal received, allowing for better signal quality depending on the signal strength coming in, but must be balanced to avoid overloading the system with too strong a signal. Thus, it can be appreciated that gain adjustment may be accomplished by adjusting the amplification circuitry 282. Accordingly, for example, when the controller 200 transitions the opener 120 to the pairing mode, the controller 200 (e.g., via the sensitivity manager 270) may also reduce the gain of the receiver 250 may lowering the amplification provided via the amplification circuitry 282.

In some embodiments, the gain reduction may be performed to accomplish a fixed amount of reduced gain. For example, gain (or amplification) may be reduced to 50%, 25%, or even 10% of normal gain (or amplification) levels while in the pairing mode. This gain reduction will ensure that only transmissions from close transmitters (e.g., the remote actuator 180) may be processed for inclusion on the authorized remote actuator list 264 in the pairing mode. However, a fixed reduction is not the only possible solution. Instead, a variable reduction of gain may be employed to ensure that only, for example, the closest transmitter may be received. In this regard, for example, gain (or amplification) levels may be reduced to some initial minimum value (including zero), and then raised until a first transmitter is detected. The first transmitter can be expected to the transmitter that is closest to the receiver 250, and therefore also the remote actuator 180 that is intended to be learned or paired. In practice, the controller 200 may reduce the gain (or amplification) level of the amplification circuitry 282 to a first value and listen a limited time for receipt of a transmission at the corresponding first value. If none is received, the controller may increase the gain by a predetermined amount and (perhaps also with prompting to ensure an additional transmission from the remote actuator 180) listen again for receipt of the transmission at the increased gain. This process may be repeated until the transmission from the remote actuator 180 is received. Within this context, the term “listen” refers to the process of receiving transmissions at an antenna and evaluating such transmissions to determine whether the transmissions have a particular characteristic in terms of signal strength, quality, or other parameters that may be of interest.

As an alternative to adjusting the gain via the amplification circuitry 282, sensitivity of the receiver 250 may be adjusted by changing properties of the filter circuitry 284. In this regard, for example, filter properties may be adjusted to introduce signal attenuation to reduce signal strength of received signals. To accomplish this, one or more additional filters may be added, or other filter properties may be adjusted to increase attenuation. As with the amplification or gain adjustments noted above, signal attenuation may be accomplished through modification of the filter circuitry 284 by the controller 200 (e.g., via the sensitivity manager 270) in either a fixed or variable manner. When fixed, the attenuation may attenuate (or aim to attenuate) incoming signals by a fixed percentage (e.g., 50%, 25%, or even 10%) or may employ varying levels of attenuation that may start large (or even maximum) and then be decreased in increments until the transmission of the remote actuator 180 can be detected.

Other adjustments that may impact sensitivity of the receiver 250 may also or additionally be performed. Thus, for example, samplings rates involved in processing by the DSP 286 may be decreased either alone or in combination with either or both of the attenuation insertion and gain reduction methodologies described above. Moreover, combinations of attenuation insertion and gain reduction may also be employed either alone or with other techniques.

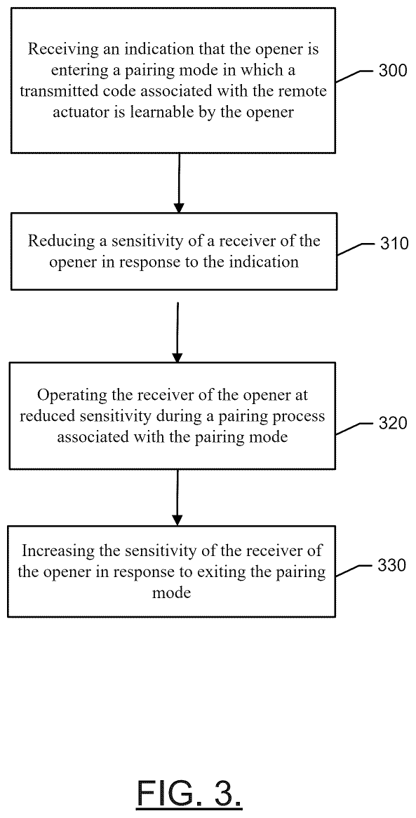

FIG. 3 is a block diagram of a method of pairing a remote actuator (e.g., with increased security) according to an example embodiment. In this regard, the method may include receiving an indication that the opener is entering a pairing mode in which a transmitted code associated with the remote actuator is learnable by the opener at operation 300 and reducing a sensitivity of a receiver of the opener in response to the indication at operation 310. The method may further include operating the receiver of the opener at reduced sensitivity during a pairing process associated with the pairing mode at operation 320, and increasing the sensitivity of the receiver of the opener in response to exiting the pairing mode at operation 330.

The operations above may be modified in some cases. Moreover, the method described above may be augmented or modified by altering individual features mentioned above or adding optional features, each of which may be combined or added in any combination. For example, reducing the sensitivity of the receiver may include decreasing a gain of amplification circuitry operably coupled to an antenna of the receiver. In this context, decreasing the gain of the amplification circuitry may include decreasing the gain by a fixed amount or a variable amount. In some example embodiments, decreasing the gain of the amplification circuitry by the variable amount may include reducing the gain to a first level and listening for a transmission from the remote actuator for a predetermined period of time, and repeating sequential steps of increasing the gain to a second and subsequent levels and listening for the transmission from the remote actuator for the predetermined period of time until the transmission from the remote actuator is detected. In an example embodiment, reducing the sensitivity of the receiver may include adjusting filter properties of filter circuitry operably coupled to an antenna of the receiver. In this context, adjusting filter properties of the filter circuitry comprises increasing attenuation to received signals at the receiver by a fixed amount or a variable amount. In an example embodiment, increasing attenuation to received signals at the receiver by the variable amount may include increasing the attenuation to a first level and listening for a transmission from the remote actuator for a predetermined period of time, and repeating sequential steps of decreasing the attenuation to a second and subsequent levels and listening for the transmission from the remote actuator for the predetermined period of time until the transmission from the remote actuator is detected.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe exemplary embodiments in the context of certain exemplary combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. In cases where advantages, benefits or solutions to problems are described herein, it should be appreciated that such advantages, benefits and/or solutions may be applicable to some example embodiments, but not necessarily all example embodiments. Thus, any advantages, benefits or solutions described herein should not be thought of as being critical, required or essential to all embodiments or to that which is claimed herein. Although specific terms are employed herein, they are used in a generic and descriptive sense only and not for purposes of limitation.

What is claimed:

1. A method of pairing a remote actuator with an opener operably coupled to a movable barrier, the method comprising:
receiving an indication that the opener is entering a pairing mode in which a transmitted code associated with the remote actuator is learnable by the opener;
reducing a sensitivity of a receiver of the opener in response to the indication;
operating the receiver of the opener at reduced sensitivity during a pairing process associated with the pairing mode; and
increasing the sensitivity of the receiver of the opener in response to exiting the pairing mode.

2. The method of claim 1, wherein reducing the sensitivity of the receiver comprises decreasing a gain of amplification circuitry operably coupled to an antenna of the receiver.

3. The method of claim 2, wherein decreasing the gain of the amplification circuitry comprises decreasing the gain by a fixed amount.

4. The method of claim 2, wherein decreasing the gain of the amplification circuitry comprises decreasing the gain by a variable amount.

5. The method of claim 4, wherein decreasing the gain of the amplification circuitry by the variable amount comprises reducing the gain to a first level and listening for a transmission from the remote actuator for a predetermined period of time, and repeating sequential steps of increasing the gain to a second and subsequent levels and listening for the transmission from the remote actuator for the predetermined period of time until the transmission from the remote actuator is detected.

6. The method of claim 1, wherein reducing the sensitivity of the receiver comprises adjusting filter properties of filter circuitry operably coupled to an antenna of the receiver.

7. The method of claim 6, wherein adjusting filter properties of the filter circuitry comprises increasing attenuation to received signals at the receiver by a fixed amount.

8. The method of claim 6, wherein adjusting filter properties of the filter circuitry comprises increasing attenuation to received signals at the receiver by a variable amount.

9. The method of claim 8, wherein increasing attenuation to received signals at the receiver by the variable amount comprises increasing the attenuation to a first level and listening for a transmission from the remote actuator for a predetermined period of time, and repeating sequential steps of decreasing the attenuation to a second and subsequent levels and listening for the transmission from the remote actuator for the predetermined period of time until the transmission from the remote actuator is detected.

10. A remotely operable movable barrier opener comprising:
a motor operable to transition the movable barrier between an open and a closed position;
a receiver configured to receive a transmitted signal from a remote transmitter; and
a controller comprising processing circuitry configured to determine whether the transmitted signal is from an authorized remote operator and configured to activate the motor in response to the transmitted signal being determined to be from the authorized remote operator,
wherein the controller is further configured to reduce a sensitivity of the receiver of the opener in response to the opener executing a pairing process and increase the sensitivity of the receiver of the opener in response to completing the pairing process.

11. The opener of claim 10, wherein reducing the sensitivity of the receiver comprises decreasing a gain of amplification circuitry operably coupled to an antenna of the receiver.

12. The opener of claim 11, wherein decreasing the gain of the amplification circuitry comprises decreasing the gain by a fixed amount.

13. The opener of claim 11, wherein decreasing the gain of the amplification circuitry comprises decreasing the gain by a variable amount.

14. The opener of claim 13, wherein decreasing the gain of the amplification circuitry by the variable amount comprises reducing the gain to a first level and listening for a transmission from the remote actuator for a predetermined period of time, and repeating sequential steps of increasing the gain to a second and subsequent levels and listening for the transmission from the remote actuator for the predetermined period of time until the transmission from the remote actuator is detected.

15. The opener of claim 10, wherein reducing the sensitivity of the receiver comprises adjusting filter properties of filter circuitry operably coupled to an antenna of the receiver.

16. The opener of claim 15, wherein adjusting filter properties of the filter circuitry comprises increasing attenuation to received signals at the receiver by a fixed amount.

17. The opener of claim 15, wherein adjusting filter properties of the filter circuitry comprises increasing attenuation to received signals at the receiver by a variable amount.

18. The opener of claim 17, wherein increasing attenuation to received signals at the receiver by the variable amount comprises increasing the attenuation to a first level and listening for a transmission from the remote actuator for a predetermined period of time, and repeating sequential steps of decreasing the attenuation to a second and subsequent levels and listening for the transmission from the remote actuator for the predetermined period of time until the transmission from the remote actuator is detected.

19. A system for remotely operating a movable barrier, the system comprising:
a movable barrier;
an opener operably coupled to the movable barrier to transition the movable barrier between an open and a closed position; and
a remote transmitter,
wherein the opener comprises:
a receiver configured to receive a transmitted signal from a remote transmitter; and
a controller comprising processing circuitry configured to determine whether the transmitted signal is from an authorized remote operator and configured to activate the motor in response to the transmitted signal being determined to be from the authorized remote operator,
wherein the controller is further configured to reduce a sensitivity of the receiver of the opener in response to the opener executing a pairing process and increase the sensitivity of the receiver of the opener in response to completing the pairing process.

20. The system of claim 19, wherein reducing the sensitivity of the receiver comprises decreasing a gain of amplification circuitry operably coupled to an antenna of the receiver, or adjusting filter properties of filter circuitry operably coupled to an antenna of the receiver.
